(19) United States
(12) Patent Application Publication
(10) Pub. No.: US 2018/0075904 A1
(43) Pub. Date: Mar. 15, 2018

(54) MEMRISTIVE CROSSBAR ARRAY HAVING MULTI-SELECTOR MEMRISTOR CELLS

(71) Applicant: Hewlett Packard Enterprise Development LP, Houston, TX (US)

(72) Inventors: Ning Ge, Palo Alto, CA (US); Jianhua Yang, Palo Alto, CA (US); Zhiyong Li, Foster City, CA (US); R. Stanley Williams, Portola Valley, CA (US)

(21) Appl. No.: 15/557,872

(22) PCT Filed: Apr. 27, 2015
(86) PCT No.: PCT/US2015/027808

§ 371 Date: Sep. 13, 2017

(51) Int. Cl. G11C 13/00; H01L 27/24; H01L 45/00

(52) U.S. Cl. CPC G11C 13/004; H01L 27/2427; H01L 45/085; H01L 45/146; G11C 13/0069; H01L 27/2463; H01L 45/1233

(57) ABSTRACT

A memristive crossbar array is described. The crossbar array includes a number of row lines and a number of column lines intersecting the row lines to form a number of cross points. A number of memristor cells are coupled between the row lines and the column lines at the cross points. A memristor cell includes a memristive memory element to store information and multiple selectors electrically coupled to the memristive memory element. The multiple selectors are to provide access to the memristive memory element.

### BACKGROUND

Crossbar memory arrays are used to store data. A crossbar memory array may be made up of a number of memory elements. Data may be stored to memory elements by assigning logic values to the memory elements within the memory arrays. For example, the memory elements may be set to 0, 1, or other values to store data in a memory element of a memory array. Much time and effort has been expended in designing and implementing nanoscale memory arrays.

Resistive memory elements referred to as memristors are devices that may be programmed to different resistance states by applying electrical voltage or currents to the memristors. After programming, the resistance state of the memristors may be read by applying an electrical bias without disturbing the resistance states when a lower electrical bias is applied. The state of the memristors remains stable over a specified time period long enough to regard the device as non-volatile.

### BRIEF DESCRIPTION OF THE DRAWINGS

The accompanying drawings illustrate various examples of the principles described herein and are a part of the specification. The illustrated examples are given merely for illustration, and do not limit the scope of the claims.

FIG. 1 is a diagram of a memristive crossbar array with multi-selector memristor cells, according to one example of the principles described herein.

FIG. 2 is a diagram of a system for accessing information in a memristive crossbar array with multi-selector memristor cells, according to one example of the principles described herein.

FIG. 3 is a diagram of a memory controller for accessing information in a memristive crossbar array with multi-selector memristor cells, according to another example of the principles described herein.

FIG. 4 is a flow diagram of a method for forming a multi-selector memristor cell, according to one example of the principles described herein.

FIGS. 5A and 5B are flow diagrams of methods for forming a multi-selector memristor cell, according to one example of the principles described herein.

FIGS. 6A and 6B are cross-sectional diagram of a multi-selector memristor cell, according to examples of the principles described herein.

Throughout the drawings, identical reference numbers designate similar, but not necessarily identical, elements.

### DETAILED DESCRIPTION

Increasingly smaller computing devices have led to an increased focus on developing smaller components, such as memory arrays. Memristor arrays made up of resistive memory elements called memristors are one example of reduced-size memory arrays. Memory arrays of memory elements such as memristors may be used in a variety of applications, including random access memory, non-volatile solid state memory, programmable logic, signal processing, control systems, pattern recognition, and other applications.

Each memory element in an array can represent at least two logic values, for example a 1 and a 0. Memory elements such as memristors may use resistance levels to indicate a particular logic value. In using a memristor as an element in a memory array, a digital operation is emulated by applying programming energy such as voltage pulses of different values, polarities, or duration to place the memristor in a “low resistance state” which resistance state is associated with a logical value, such as “1.” Similarly, a voltage pulse of a different polarity, value, or duration may place the memristor in a “high resistance state,” which resistance state is associated with another logical value, such as “0.”

The ability to change a memristor resistance state is dependent on a switching voltage of the memristor. For example, each memristor has a switching voltage which refers to a voltage potential across a memristor which effectuates a change in the resistance state of the memristor. For example, a switching voltage of a memristor may be between 1-2 volts (V). In this example, a voltage potential across the memristor that is greater than the switching voltage (i.e., the 1-2 V) causes the memristor to change between resistance states. Throughout the specification reference is made to a supplied voltage or applied voltage; however, in some examples, the programming energy may be supplied by a current source.

To determine what resistance state, and corresponding logic value, is indicated by a memristor, an output current is collected and analyzed. For example, if a write voltage is applied to a target memory element, a write current passing through the target memory element is collected. Based on the write voltage and the collected write current, a resistance level of the target memory element and corresponding written logic value is ascertained. Similarly, if a read voltage is applied to a target memory element, a current passing through the target memory element is collected. Based on the read voltage and the collected read current, a resistance level of the memristor and the corresponding stored logic value is ascertained. While crossbar memory arrays offer high density storage, certain characteristics may affect their usefulness in storing information.

For example, in a crossbar array a first number of conducting lines (row lines) and a second number of conducting lines (column lines) are positioned to form a grid, with memory elements disposed at each intersection. A voltage potential is applied across a memory element by passing voltages along a row line and column line that correspond to a target memory element. In applying a portion of an access voltage to a target row line and another portion of the access voltage to a target column line, other memory elements that fall along these target lines that are not the target memory element may also see a voltage drop, albeit a voltage drop smaller than the voltage drop across the target memory element. The voltage potential across these partially-selected memory elements generates additional current paths in the crossbar array. These additional current paths are referred to as sneak currents and are undesirable as they are noise and obfuscate the intended target output current. Large sneak currents may lead to a number of issues such as saturating the current of driving transistors and increasing power consumption. Moreover, large sneak currents may introduce large amounts of noise which can lead to inaccurate or ineffective memory reading and writing operations.

Accordingly, in some examples, a selector may be coupled to a memory element. A selector is an element that is used to either allow or prevent current from flowing to a corresponding memory element. In a cross bar array, if a memory element is not targeted, it may be desirable for current through the memory element to be suppressed. A selector works by suppressing current less than a certain amount. Accordingly a portion of a sneak current may be reduced. Thus a selector works to isolate a target memory cell and reduce overall sneak current in the crossbar array.

Selectors may be nonlinear meaning that a certain change in voltage applied across the selector may drive a disproportionate change in the current passing through the selector. In other words, a nonlinear selector is used to isolate unselected memory elements and thereby reduce sneak current in an array such as a crossbar array. However, while nonlinear selectors reduce some sneak current inherent in a crossbar array, some sneak current may still exist. Moreover, single selectors that are nonlinear enough to reduce significant amounts of sneak current can be difficult, and costly, to manufacture.

The devices and methods described herein alleviate these and other complications. More specifically, the present systems and methods describe memristor cells that include multiple selectors. The multiple selectors together may further reduce the ability of a non-selecting voltage, applied to a non-target memristor cell, to pass a sneak current as an output.

Specifically, the present specification describes a memristive crossbar array. The memristive crossbar array includes a number of row lines and a number of column lines intersecting the row lines to form a number of cross points. A number of memristor cells are coupled between the row lines and the column lines at the cross points. A memristor cell includes a memristive memory element to store information and multiple selectors electrically coupled to the memristive memory element. The multiple selectors provide access to the memristive memory element.

The present specification describes a system for accessing information in a memristive crossbar array. The system includes a memristive crossbar array that includes a number of memristor cells coupled between row lines and column lines of the memristive crossbar array. A memristor cell includes a memristive memory element to store information and multiple selectors electrically coupled to the memristive memory element. The multiple selectors provide access to the memristive memory element. The system also includes a memory controller to provide access to the memristive memory element by providing an access voltage to a corresponding memristor cell.

The present specification describes a method for making a memristive crossbar array. A memristive memory element that includes a first memristor electrode, a switching oxide disposed adjacent to the first electrode, and a second memristor electrode disposed adjacent to the switching oxide is provided. Multiple selectors are also provided, a selector including a first selector electrode, a second selector electrode, and a selector active region disposed between the first selector electrode and the second selector electrode. The multiple selectors are electrically coupled in series to the memristive memory element.

The devices and methods described herein may allow for reduced complexity in manufacturing as complex single selector devices are avoided in favor of simple multi-selector devices. Moreover, including multiple selectors in a memristor cell reduces the effects of sneak current as a voltage that passes to an individual selector is further reduced based on a voltage divider effect between the multiple selectors. In other words, the nonlinearity of multiple selectors may be greater than could be achieved by a single selector thus increasing the distinction between a current output from a target memristor cell and sneak current output from non-target memristor cells.

As used in the present specification and in the appended claims, the term “memristor” refers broadly to a passive two-terminal circuit element that changes its electrical resistance under sufficient electrical bias.

Further, as used in the present specification and in the appended claims, the term “target” refers broadly to a memory element that is to be written to or read from. A target first line and a target second line may be first lines and second lines that correspond to the target memory element.

Still further, as used in the present specification and in the appended claims, the term “partially-selected memory element” refers broadly to a memory element that falls along a target row line or a target column line. The partially-selected memory elements may have a voltage drop that is less than a voltage drop of the target memory element. A partially-selected memristor receives either a first portion of the access voltage passed through a target row line or the second portion of the access voltage passed through a target column line.

Still further, as used in the present specification and in the appended claims the term “access voltage” refers broadly to a voltage that is applied to a memory element. The access voltage may be a write voltage that is larger than a switching voltage of a memory element, or may be a read voltage that is less than the switching voltage of the memory element. By comparison, a non-access voltage refers broadly to a voltage that is not greater than either a read voltage or a write voltage. The access voltage may be greater than a threshold voltage for a selector, the threshold voltage being a voltage sufficient to activate the selector into an increased conductivity state and a non-access voltage may be less than the threshold voltage for a selector.

Still further, as used in the present specification and in the appended claims, the term “nonlinear” refers broadly to a property of the selector, memristor, or selector-memristor combination wherein a change in voltage applied across the selector or memristor results in a disproportionate change in current flowing through the selector, memristor, or selector-memristor combination, respectively.

Even further, as used in the present specification and in the appended claims, the term “volatile” refers broadly to a device that returns to an original state within a given period of time after an applied voltage is removed. For example, a volatile selector placed in a low resistance state due to the application of voltage, returns to a high resistance state after a certain time, called the relaxation time, after the applied voltage is removed from the selector.

Even further, as used in the present specification and in the appended claims, the term “suppressed current level” may refer to a level to which current is suppressed by a selector. For example, a suppressed current for a selector may be a value I, meaning that currents less than I are suppressed by the selector such that no current is passed to the corresponding memristive memory element.

Even further, as used in the present specification and in the appended claims, “a”, “an”, and “the” are intended to include the plural forms as well as the singular forms, unless the context clearly indicates otherwise.

Even further, as used in the present specification and in the appended claims “multiple” refers to any positive number greater than 1.

Yet further, as used in the present specification and in the appended claims, the term “a number of” or similar language may include any positive number including 1 to infinity; zero not being a number, but the absence of a number.

In the following description, for purposes of explanation, numerous specific details are set forth in order to provide a thorough understanding of the present systems and methods, It will be apparent, however, to one skilled in the art that the present apparatus, systems, and methods may be practiced without these specific details. Reference in the specification to “an example” or similar language indicates that a particular feature, structure, or characteristic described is included in at least hat one example, but not necessarily in other examples.

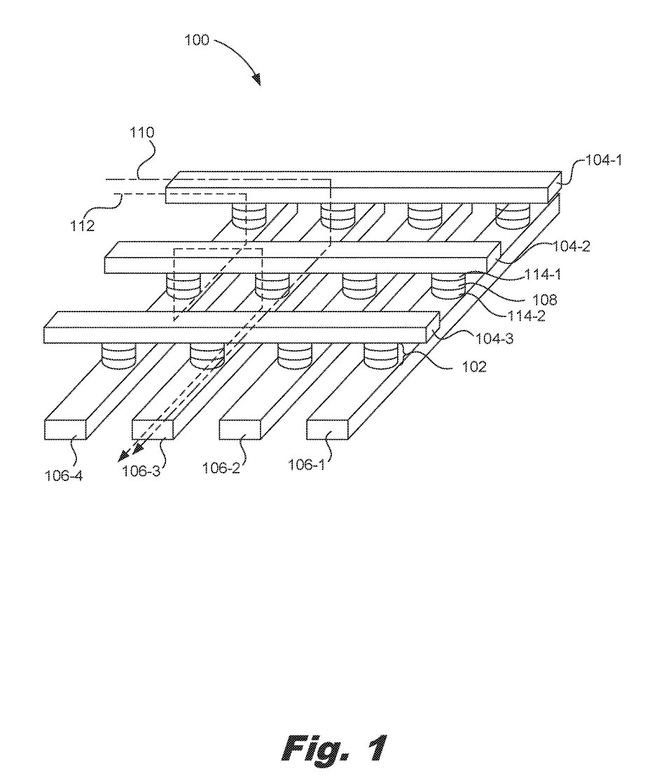

FIG. 1 is a diagram of a memristive crossbar array (100) with multi-selector memristor cells (102), according to one example of the principles described herein. As described above, a crossbar array (100) is used in a variety of applications, including random access memory, non-volatile solid state memory, programmable logic, signal processing, control systems, pattern recognition, and other applications. The crossbar array (100) includes a number of row lines (104-1, 104-2, 104-3). The row lines (104) may be approximately parallel to one another. The crossbar array (102) also includes a number of column lines (106-1, 106-2, 106-3, 106-4). The column lines (106) may also be approximately parallel to one another. Even though three row lines (104) and four column lines (106) are depicted in FIG. 1, any number of row lines (104) and column lines (106) may be present in the crossbar array (102). As depicted in FIG. 1, the row lines (104) and the column lines (106) may be orthogonal to one another. The two layers of lines (104, 106) form a crossbar, each of the row lines (104) overlaying the column lines (106) and coming into close contact with each column line (106) at cross points that represent the closest contact between each line. While FIG. 1 depicts the lines (104, 106) as having rectangular cross sections, the lines (104, 106) can have other cross sectional geometries including square, circular, elliptical or more complex cross sections.

The lines (104, 106) effectuate voltage drops across memristor cells (102) coupled between row lines (104) and column lines (106) at the cross points. For simplicity one memristor cell (102) is indicated with a reference number. For example, a target row line (104-1) that corresponds to a target memristor cell (102) may supply a first portion of an access voltage to the target memristor cell (102) while a target column line (106-3) applies a second portion of the access voltage to the target memristor cell (102). The difference between the first portion and second portion generates a voltage drop across the target memristor cell (102) equal to the access voltage. The access voltage may be either a voltage less than the switching voltage of the target memristor cell (102), i.e., a read voltage, or may be greater than the switching voltage of the target memristor cell (102), i.e., a write voltage. In some examples, the voltage supplied by the target row line (104-1) may be the access voltage and the target column line (106-3) may be grounded. The remaining non-target row lines (104-2, 104-3) and non-target column lines (106-1, 106-2, 106-4) may see a non-access voltage drop that is less than a threshold voltage of the selectors.

At the intersection of each of the number of row lines (104) and each of the number of column lines (106) is a memristor cell (102). A memristor cell (102) includes a memristive memory element (108) to store information. In some examples a memristive memory element (108) is a memristor; a memristor being a non-volatile memory element (108). For simplicity one memristor (108) is indicated with a reference number.

A memristor can be used to represent a number of bits of data. For example, a memristor in a low resistance state may represent a logic value of “1.” The same memristor in a high resistance state may represent a logic value of “0.” Each logic value is associated with a resistance state of the memristor such that data can be stored in a memristor by changing the resistance state of the memristor. This may be done by applying an access voltage to a target memristor cell (102) by passing voltages to target lines (104, 106) that correspond to the target memristor cell (102).

A memristor is a specific type of memristive memory element (108) that can change resistances by transporting dopants within a switching layer to increase or decrease the resistivity of the memristor. As a sufficient voltage is passed across the memristor, the dopants become active such that they move within a switching layer of the memristor and thereby change the resistance of the memristor.

A memristor is non-volatile because the memristor maintains its resistivity, and indicated logic value, even in the absence of a supplied voltage. In this manner, the memristors are “memory resistors” in that they “remember” the last resistance that they had.

Memristors can be made in a number of geometries and using a variety of materials. One form is a metal-insulator-metal memristor. The term metal is meant to refer broadly to indicate a conductor, for instance doped silicon. A memristor may include a bottom electrode (metal), a switching layer (insulator), and a top electrode (metal). The switching layer may be an insulator between the bottom electrode and the top electrode. For example, in a first state, the switching layer may be insulating such that current does not readily pass between the bottom electrode and the top electrode. Then, during a switching event, the switching layer may switch to a second state, becoming conductive. In a conductive state, the switching layer allows a memristor to store information by changing the memristor state.

In some examples, the top electrode and bottom electrode of the memristor may be formed from a metallic material such as tantalum or a tantalum-aluminum alloy, or other conducting material such as titanium, titanium nitride, copper, aluminum, platinum, and gold among other metallic materials. The switching layer may be made of a metallic oxide. Specific examples of switching layer materials include magnesium oxide, titanium oxide, zirconium oxide, hafnium oxide, vanadium oxide, niobium oxide, tantalum oxide, chromium oxide, molybdenum oxide, tungsten oxide, manganese oxide, iron oxide, cobalt oxide, copper oxide, zinc oxide, aluminum oxide, gallium oxide, silicon oxide, germanium oxide, tin dioxide, bismuth oxide, nickel oxide, yttrium oxide, gadolinium oxide, and magnesium oxide, among other oxides. In addition to the binary oxides presented, the switching layer may be ternary and complex oxides such as silicon oxynitride.

A memristor may be classified as an anion device which includes an oxide insulator as the switching layer. Examples of such oxide insulators include transition metal oxides, complex oxides, and large band gap dielectrics in addition to other non-oxide materials, In this example, a tantalum oxide may be an example of a switching layer in an anion device. In an anionic device, the switching mechanism is the formation of oxygen vacancies in the oxide that are positively charged and therefore lead to the formation of conducting channels in the switching layer. By comparison, in a cation device the conducting channel is formed from an electrochemically active metal such as copper or silver. In some examples, a memristor may be both an anionic device and a cationic device. For example, an aluminum-copper-silicon alloy oxide based memristor could be an anionic device when the copper concentration is low or a cationic device when the copper concentration is high.

As described above, memristors within a crossbar array (100) indicate a logic value which may be determined based on a resistance state of the memristive memory element (108). To read the resistance state of a particular memristive memory element (108), an access voltage is applied to a memristive memory element (108). For example, to read the resistance of a target memristive memory element (108) a first portion of the access voltage, i.e., a positive voltage may be applied to a target row line (104-1). Similarly, a second portion, for example, a negative polarity voltage may be applied to a target column line (106-3). The resulting voltage drop across the memristive memory element (108) creates a current flow that is indicated by the short/long dashed line (110). Sensing circuitry measures the target output current along the target column line (106-3). From the target output current a device determines the resistance, and logic value, indicated by the target memristive memory element (108).

However, as described above, the applied voltages also cause electron flow across other memristive memory elements (108), such as those elements that share the target row line (104-1) and target column line (106-3) with the target memristive memory element (108) and other memory elements. The voltage drop across the partially-selected memory elements (108), and other voltage drops that may be the result of voltages less than the access voltage being passed across non-target lines (104-2, 104-3, 106-1, 106-2, 106-4) generate sneak currents, such as the sneak current indicated by the dashed line (112). Sneak currents can obscure the reading of the target memristive memory element (108) resistance state. The impact of the sneak current increases as the size of the crossbar array (100) increases such that large enough sneak currents may make an accurate reading of a target memristive memory element (108) impossible.

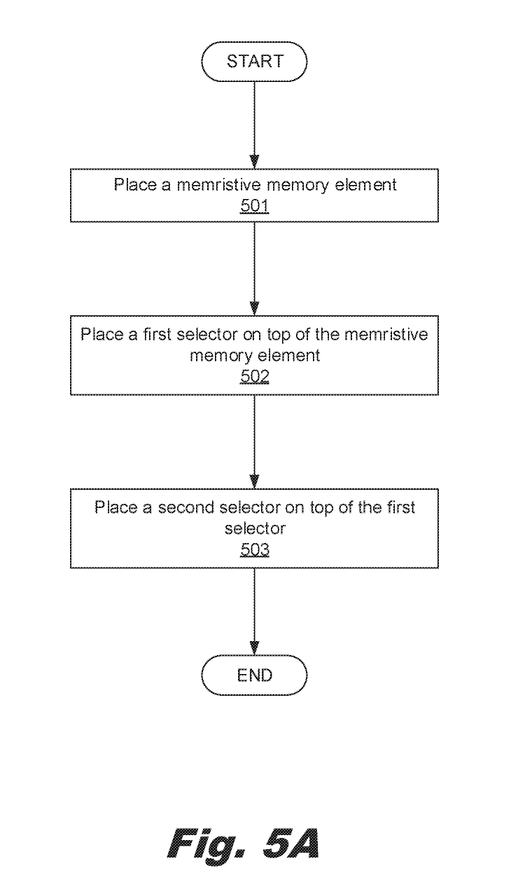

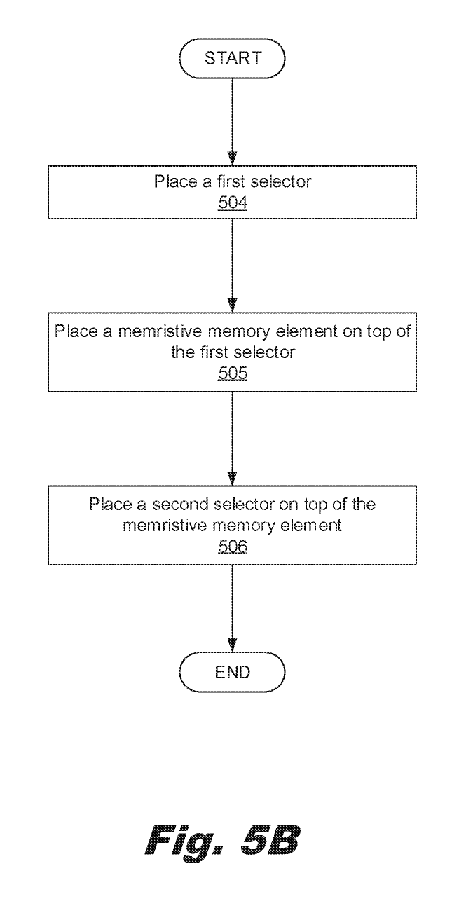

Accordingly, the present specification describes devices and methods for reducing the sneak current, and detection of sneak current, in an array such as a crossbar array (100). In this example, each memristor cell (102) includes multiple selectors (114), for example at least two selectors (114-1, 114-2). For simplicity two selectors (114-1, 114-2) pertaining to one memristor cell (102) are indicated in FIG. 1 with a reference number. Moreover, while FIG. 1 depicts the memristive memory element (108) sandwiched between the selectors (114-1, 114-2), any orientation may be used. For example, the memristive memory element may be on top of, or beneath both selectors (114) as depicted in FIG. 5B.

A selector (114) is an element that allows electrons to flow through a memristive memory element (108) or that prevents electrons from flowing through the memristive memory element (108). For example, a selector (114) may suppress currents lower than a certain amount while allowing currents greater than the certain amount to pass. When a supplied voltage generates a current that is less than the certain amount, the selector (114) suppresses the current and no current is seen by the memristive memory element (108). As such, no current flows through the memristive memory element (108). Similarly, in this example, when the supplied voltage generates a current that is greater than the certain amount, the selector (114) allows passage of the current such that the supplied voltage is seen by the memristive memory element (108) and a current is passed through the memristive memory element (108) and an output current received by the sensing circuitry along the column lines (106).

Using at least two selectors (114) per memristor cell (108) may further decrease the likelihood of sneak currents in the crossbar array (100). For example, as described above a nonlinear selector (114) outputs a current disproportionate relative to different input voltages. For example, for a given non-access voltage, V/2, a current output from a nonlinear selector (114) has a value I₁. By comparison, for a given access voltage, V, which is 2 times greater than the non-access voltage, a current output from a nonlinear selector (114) is a value I₂ which value is 500 times greater than the value I₁. In other words, the difference in output current, (I₂-I₁) may be disproportionate to the difference in input voltage, (V-V/2) by a factor of 250. Including multiple selectors (114) in a memristor cell (102) further increases the nonlinearity as the nonlinearity of each selector (114) is added together, creating a larger nonlinearity. For example, if a selector (114) has a nonlinearity of approximately 500, the nonlinearity of two of these selectors (114) may be approximately 1000, In other words, the nonlinearity of the at least two selectors (114) combined may be at least 1,000. As will be described below, in some examples, the selectors (114) may be asymmetrical, each selector being tuned to optimize different operations. For example, one selector (114) may be tuned to optimize a reset operation by being tuned to be nonlinear for a negative polarity and another selector (114) may be tuned to optimize a set operation by being tuned to be nonlinear for a positive polarity.

Including at least two nonlinear selectors (114) may further reduce sneak current as the voltage seen by a particular selector (114) is reduced due to the voltage divider effect between the two selectors (114-1, 114-2). For example, assume a non-access voltage of 0.5 volts (V) is applied to a selector (114) that suppresses current generated by 6 V. While below the threshold voltage of the selector (114), this non-access voltage may still result in some sneak current passing through to a corresponding memristive memory element (108) due to imperfections in the selector (114). By comparison, using at least two selectors (114-1, 114-2) each suppressing currents generated by a voltage less than 0.6 V, the voltage seen by each selector due to a non-access voltage of 0.5 V would be approximately 0.25 V due to the voltage divider effect between the two. Accordingly, this non-access voltage would not result in a sneak current for the corresponding memristor cell (102) as neither selector (114) sees a voltage that generates a current that overcomes, or is close to the suppressed current level.

Still further, using two selectors (114) may allow for a higher operating voltage, i.e., access voltage to be used. For example, as described above using a single selector (114), the suppressed current level of the single selector (114) may restrict how large an access voltage may be used. However, using multiple selectors (114) and based on the above described voltage divider effect; a larger access voltage may be used without the likelihood of an inadvertent passage of current through a selector (114). Such higher voltages applied may also lead to higher output currents which may facilitate easier array operation.

In some examples, the at least two selectors (114-1, 114-2) may be volatile selectors (114). A volatile selector (114) refers to a selector that does not retain its state when electrical current is removed from it. For example, a volatile selector (114) may return to its non-powered state after a certain period of time after an applied voltage has been removed. This certain period of time may be referred to as the selector (114) relaxation time. For example, a volatile selector (114) may initially be in a high resistance state. Upon application of an access voltage that generates a current greater than the suppressed current level relating to the volatile selector (114), the volatile selector (114) enters a low resistance state such that current is passed to a corresponding memristive memory element (108). When the access voltage is removed, the volatile selector (114) returns to a high resistance state after a certain period of time. In some examples, the volatile selector (114) returns to its high resistance state within a short period of time, for example 1 microsecond after a current is no longer greater than the suppressed current level of the volatile selector (114). Such a quick “relaxation time” may allow for the memory device to be read from at a faster rate.

For example, using volatile selectors (114) as the at least two selectors (114) in a memristor cell (108) may allow a selector to be quickly re-established at a high resistance state thus avoiding passage of current during a subsequent access operation. More specifically, during a first access operation a first memristor cell (102) may be targeted and the corresponding volatile selectors (114) placed in a low resistance state. To initiate a second access operation of a second memristor cell (102) the volatile selectors (114) of the first memristor cell (102) should return to a high resistance state. If these selectors (114) remain in their low resistance state while attempting to access the second memristor cell (102), the selectors (114) of the first memristor cell (102) may allow additional sneak current to pass through obfuscating the reading/writing of a value to the second memristor cell (102). Accordingly, volatile selectors (114) that return quickly to their original state, a high resistance state, allow subsequent access operations to be performed while reducing the overall sneak current in the crossbar array (100). Moreover, volatile selectors (114) may provide increased current density for the crossbar array (100). For example, a volatile selector (114) formed to have a volatile conductive bridge may supply a higher current level.

The at least two selectors (114) may be asymmetric selectors. For example, one of the multiple selectors (114) may be tuned to optimize at one polarity and another of the at least two selectors (114) may be tuned to optimize at a second, and opposite polarity. In other words, a first selector (114-1) may be formed to be highly nonlinear for a negative polarity, thus providing desirable nonlinearity for a reset operation, a reset operation being changing a memristive memory element (102) from a low resistance state to a high resistance state. The second selector (114-2) may be formed to be highly nonlinear for a positive polarity, thus providing desirable nonlinearity for a set operation, a set operation being changing a memristive memory element (102) from a high resistance state to a low resistance state. Forming a selector (114) to facilitate nonlinearity in a particular direction may be accomplished by selecting particular materials, thicknesses, etc. for the at least two selectors (114). For example, an asymmetric selector (114) may rely on some form of asymmetry in the device stack structure. In a specific example, the selectors (114) may include similar switching materials, but include top and bottom electrodes made of different material to provide the asymmetry. In another example, the selectors (114) may include similar top and bottom electrode materials, but may have asymmetry due to different materials used for the switching material. Implementing asymmetric selectors (114) provides for high nonlinearity in both directions. For example, when using one selector it may be unreasonable, expensive, or impossible to form a selector with nonlinearity in both directions. Accordingly, using at least two selectors (114) each can be designed to provide high nonlinearity in one direction, making them cheaper and simpler to manufacture, yet when coupled together they provide nonlinearity in both directions.

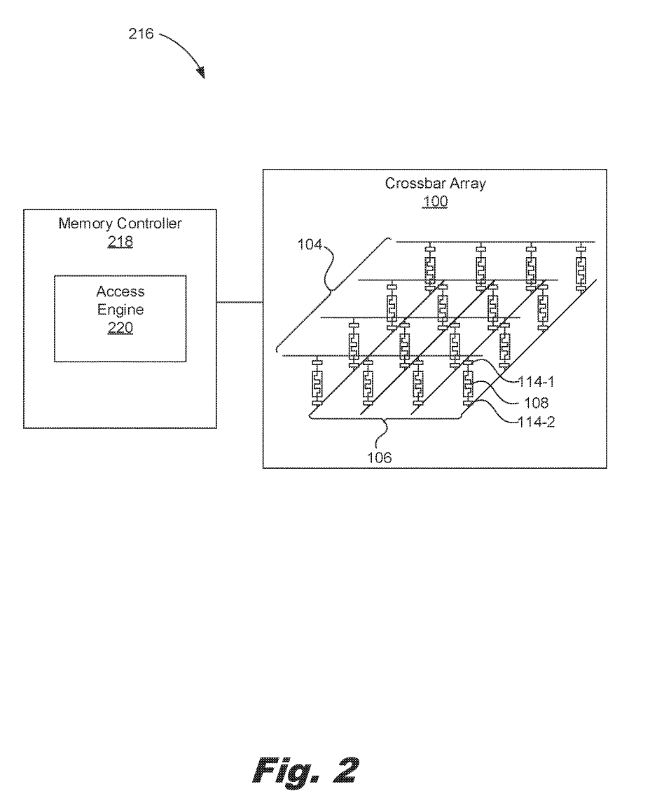

FIG. 2 is a diagram of a system (216) for accessing information in a memristive crossbar array (100) with multi-selector memristor cells (FIG. 1, 102), according to one example of the principles described herein. The system (216) may be implemented in an electronic device. Examples of electronic devices include servers, desktop computers, laptop computers, personal digital assistants (PDAs), mobile devices, smartphones, gaming systems, and tablets, among other electronic devices. The system (216) may be utilized in any data processing scenario including, stand-alone hardware, mobile applications, through a computing network, or combinations thereof. Further, the system (216) may be used in a computing network, a public cloud network, a private cloud network, a hybrid cloud network, other forms of networks, or combinations thereof.

The system (216) includes a memristive crossbar array (100). As described in FIG. 1, the crossbar array (100) includes a number of row lines (104), a number of column lines (106), and a number of memristor cells (FIG. 1, 102) disposed at cross points of the row lines (104) and the column lines (106). Specifically, each memristor cell (FIG. 1, 102) includes a memristive memory element (108) and at least two selectors (114), such as volatile selectors. The selectors (114) may be serially coupled to the memristive memory element (108). While FIG. 2 depicts the memristive memory element (108) as sandwiched between selectors (114), any orientation may be used, for example, from bottom to top the memristor cell (FIG. 1, 102) stack may include a memristive memory element (108), first selector (114-1), and second selector (114-2). In another example, from bottom to top the memristor cell (FIG. 1, 102) stack may include a first selector (114-1), second selector (114-2), and memristive memory element (108) as depicted in FIG. 5B.

As described above, the selectors (114-2) work together to provide access to the memristive memory element (108). For example, to both read information from and write information to a memristive memory element (108), the threshold voltages of both the selectors (114) are overcome by an applied access voltage.

The system (216) also includes a memory controller (218) to provide an access voltage to a corresponding memristor cell (FIG. 1, 102). The memory controller (218) may include an access engine (220). The engine refers to a combination of hardware and program instructions to perform a designated function. The engine may be hardware. For example, the engine may be implemented in the form of electronic circuitry (e.g., hardware). The engine may include its own processor, but one processor may be used by all the engines. For example, the engine may include a processor and memory. Alternatively, one processor may execute the designated function of the engine.

In response to a read request, an access engine (220) of the memory controller (218) provides a read voltage, which is less than a switching voltage of the target memristive memory element (108), to the corresponding row line (104) and column line (106) of the target memristor cell (FIG. 1, 102). In other words, for a read voltage to pass through the target memristive memory element (108), each selector (114) is activated.

Similarly, in response to a write request, an access engine (220) of the memory controller (218) provides a write voltage to the corresponding row line (104) and column line (106) of the target memristor cell (FIG. 1, 102), which write voltage may be greater than a switching voltage of the target memristive memory element (108). In other words, for a write voltage to pass through the target memristive memory element (108), each selector (114) is activated.

In addition to passing access voltages to the target row lines (104) and target column lines (106), the memory controller (218) also passes non-access voltages to the remaining row lines (104) and column lines (106).

The memory controller (218) may include sensing circuitry. The sensing circuitry senses a target output associated with a target memristive memory element (108). The sensing circuitry may collect a current along a target column line (106). For example, as an access voltage is applied to a target memory element (108), a current is generated. This current may be collected along the column line (106) that corresponds to the target memristive memory element (108) and from the target current a resistance state, and corresponding logic value, of the target memory element (108) is ascertained.

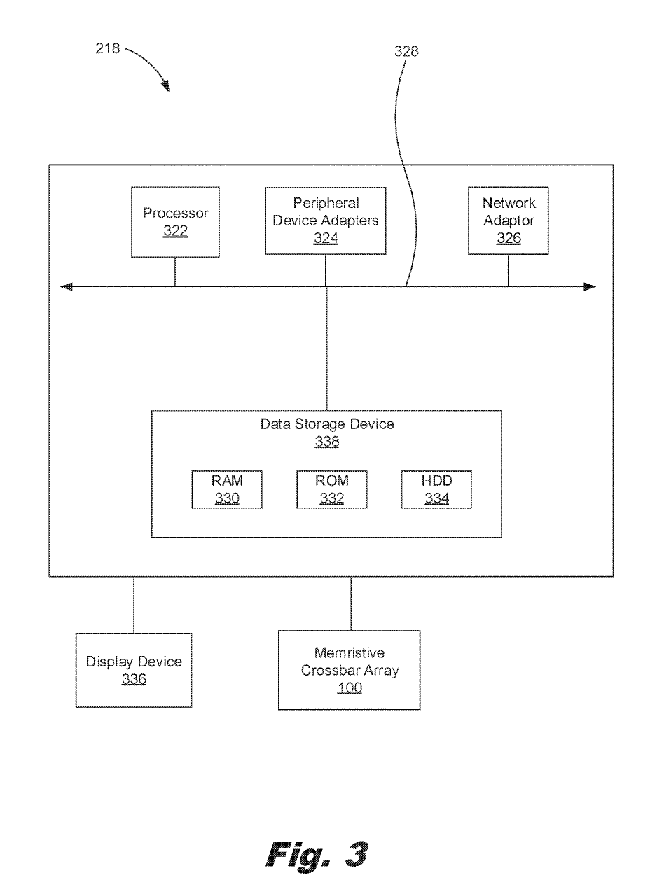

FIG. 3 is a diagram of a memory controller (218) for accessing information in a memristive crossbar array (100) with multi-selector memristor cells (FIG. 1, 102), according to another example of the principles described herein. To achieve its desired functionality, the memory controller (218) includes various hardware components. Specifically, the memory controller (218) includes a processor (322) and computer program code. The computer program code is communicatively coupled to the processor (322). The computer program code may be stored in a data storage device (338) of the memory controller (218).

The memory controller (218) may be implemented in an electronic device. Examples of electronic devices include servers, desktop computers, laptop computers, personal digital assistants (PDAs), mobile devices, smartphones, gaming systems, and tablets, among other electronic devices.

The memory controller (218) may be utilized in any data processing scenario including, stand-alone hardware, mobile applications, through a computing network, or combinations thereof. Further, the memory controller (218) may be used in a computing network, a public cloud network, a private cloud network, a hybrid cloud network, other forms of networks, or combinations thereof. In one example, the methods provided by the memory controller (218) are provided as a service over a network by, for example, a third party.

To achieve its desired functionality, the memory controller (218) includes various hardware components. Among these hardware components may be a number of processors (322), a data storage device (338), a number of peripheral device adapters (324), and a number of network adapters (326). These hardware components may be interconnected through the use of a number of busses and/or network connections. In one example, the processor (322), data storage device (338), peripheral device adapters (324), and a network adapter (326) may be communicatively coupled via a bus (328).

The processor (322) may include the hardware architecture to retrieve executable code from the data storage device (338) and execute the executable code. The executable code may, when executed by the processor (322), cause the processor (322) to implement at least the functionality of accessing information in a memristive crossbar array (100). The functionality of the memory controller (218) is in accordance to the methods of the present specification described herein. In the course of executing code, the processor (322) may receive input from and provide output to a number of the remaining hardware units.

The data storage device (338) may store data such as executable program code that is executed by the processor (322) or other processing device. As will be discussed, the data storage device (338) may specifically store computer code representing a number of applications that the processor (322) executes to implement at least the functionality described herein.

The data storage device (338) may include various types of memory modules, including volatile and nonvolatile memory. For example, the data storage device (338) of the present example includes Random Access Memory (RAM) (330), Read Only Memory (ROM) (332), and Hard Disk Drive (HDD) memory (334). Many other types of memory may also be utilized, and the present specification contemplates the use of many varying type(s) of memory in the data storage device (338) as may suit a particular application of the principles described herein. In certain examples, different types of memory in the data storage device (338) may be used for different data storage needs. For example, in certain examples the processor (322) may boot from Read Only Memory (ROM) (332), maintain nonvolatile storage in the Hard Disk Drive (HDD) memory (334), and execute program code stored in Random Access Memory (RAM) (330).

The data storage device (38) may include a computer readable medium, a computer readable storage medium, or a non-transitory computer readable medium, among others. For example, the data storage device (338) may be, an electronic, magnetic, optical, electromagnetic, infrared, or semiconductor system, apparatus, or device, or any suitable combination of the foregoing. More specific examples of the computer readable storage medium may include, for example, the following: an electrical connection having a number of wires, a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store computer usable program code for use by or in connection with an instruction execution system, apparatus, or device. In another example, a computer readable storage medium may be any non-transitory medium that can contain, or store a program for use by or in connection with an instruction execution system, apparatus, or device.

The hardware adapters (324, 326) in the memory controller (218) enable the processor (322) to interface with various other hardware elements, external and internal to the memory controller (218). For example, the peripheral device adapters (324) may provide an interface to input/output devices, such as, for example, display device (336), a mouse, or a keyboard. The peripheral device adapters (324) may also provide access to other external devices such as an external storage device, a number of network devices such as, for example, servers, switches, and routers, client devices, other types of computing devices, and combinations thereof.

The display device (336) may be provided to allow a user of the computing system (FIG. 2 216) to interact with and implement the functionality of the computing system (FIG. 2, 216). The peripheral device adapters (324) may also create an interface between the processor (322) and the display device (336), a printer, or other media output devices. The network adapter (326) may provide an interface to other computing devices within, for example, a network, thereby enabling the transmission of data between the computing system (FIG. 2, 216) and other devices located within the network.

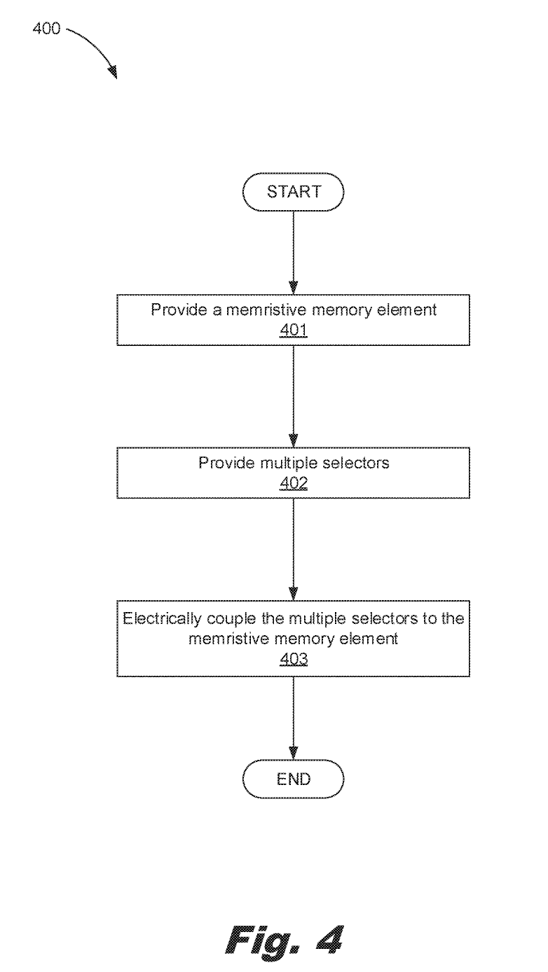

FIG. 4 is a flow diagram of a method (400) for forming a multi-selector memristor cell (FIG. 1, 102), according to one example of the principles described herein, The method (400) includes providing (block 401) a memristive memory element (FIG. 1, 108). As described above, the memristive memory element (FIG. 1, 108) may be a memristor with a metal-insulator-metal structure. In other words, a first memristor electrode is provided, and a switching oxide may be disposed adjacent to, for example on a top surface of, the first memristor electrode. Similarly, a second memristor electrode may be disposed adjacent to, for example on a top surface of, the switching oxide.

The method (400) also includes providing (block 402) multiple selectors (FIG. 1, 114). Similar to the memristor, a selector (FIG. 1, 114) may be layered to form a layered structure including a first selector electrode, a second selector electrode, and an active region disposed between the first selector electrode and the second selector electrode.

The method (400) also includes electrically coupling (block 403) the multiple selectors (FIG. 1, 114) to the memristive memory element (FIG. 1, 108). For example the selectors (FIG. 1, 114) may be coupled serially, in any orientation, to the memristive memory element (FIG. 1, 108). Doing so allows the selectors (FIG. 1, 114) to either permit, or prevent current from flowing through a corresponding memristive memory element (FIG. 1, 108).

While FIG. 4 indicates provision of the various components in a particular order, FIG. 4 does not indicate any particular layering of the components. For example, as depicted in FIG. 5A, the memristive memory element (FIG. 1, 108) may be placed (block 501), and a first selector (FIG. 1, 114-1) placed (block 502) on top of the memristive memory element (FIG. 1, 108) and a second selector (FIG. 1, 114-2) placed (block 503) on top of the first selector (FIG. 1, 114-1). In another example, as depicted in FIG. 5B, the first selector (FIG. 1, 114-1) may be placed (block 504), and a memristive memory element (FIG. 1, 108) placed (block 505) on top of the first selector (FIG. 1, 114-1) and a second selector (FIG. 1, 114-2) placed (block 506) on top of the memristive memory element (FIG. 1, 108). While FIGS. 5A and 5B make specific reference to particular orders of the selectors (FIG. 1, 114) and memristive memory elements (FIG. 1, 108) any order of the components may be used. For example, from bottom-to-top the stack may be memristive memory element (FIG. 1, 108), first selector (FIG. 1, 114-1), and second selector (FIG. 1, 114-2).

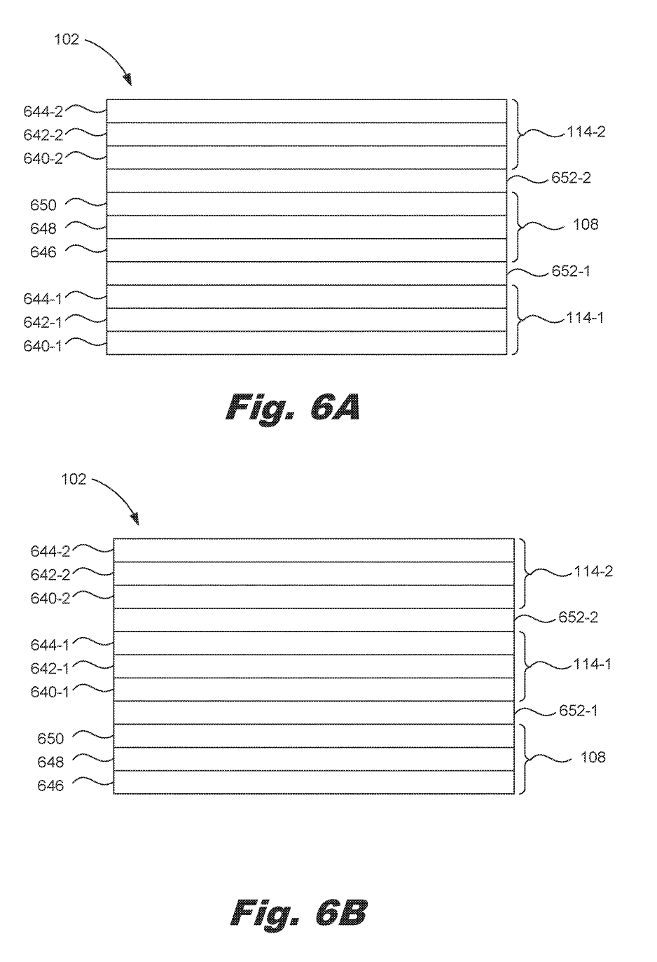

FIGS. 6A and 6B are cross-sectional diagram of multi-selector memristor cells (102), according to examples of the principles described herein. Specifically, FIG. 6A depicts a memristor cell (102) where the memristive memory element (108) is sandwiched between selectors (114-1, 114-2) and FIG. 6B depicts a memristor cell (102) where one of the selectors (114-1) is sandwiched between the memristive memory element (108) and another selector (114-2). While FIGS. 6A and 6B depict a particular layering of the different components, any layering may be used.

As described above, the memristive memory element (108) may include a number of layers. Specifically, the memristive memory element (108) may include a first memristor electrode (646) and a second memristor electrode (650) described above as a bottom electrode and top electrode, respectively. The memristive memory element (108) may also include a switching oxide (648) as described previously.

Similarly, as described above, each selector (114-1. 114-2) may include a number of layers, Specifically each selector (114-1, 114-2) may include a first electrode (640-1, 640-2) that may be disposed vertically on the bottom of the respective selector (114) stack. Similarly, each selector (114-1, 114-2) may include a second electrode (644-1, 644-2) that may be disposed vertically on the top of the respective selector (114) stack. The first electrode (640) and the second electrode (644) may be made of any conductive material such as platinum, tantalum, titanium nitride and tantalum nitride. Sandwiched between the electrodes (640, 644) is an active region (642). The active region (642) of the selector (114) may include cationic species that aggregate to form a conductive channel between the first electrode (640) and the second electrode (644) when an access voltage is applied. In other cases, the conductive channel may be formed by the insulator-metal-transition or charge trapping mechanism. These conductive channels may break down when the access voltage is removed. In some examples, such as tunneling barrier based selectors, there is no conductive channel and the conductance of the selector material decreases with increasing voltage uniformly in a volatile fashion. The active region (642) may be formed of any number of materials including vanadium oxide, titanium oxide, niobium oxide, and silicon oxide. In some examples, the active region (642) may be doped with highly mobile species such as copper or silver that move to form the conducting channel as described above. Each of the electrodes (640, 644) may also include amounts of the highly mobile species.

In some examples interface layers (652-1, 652-2) are disposed between each of the selectors (114) and the memristive memory element (108). The interface layers (652) may prevent unwanted diffusion, chemical contamination, or other reactions between the corresponding layers.

Certain examples of the present disclosure are directed to a memristor cell (102) with multiple selectors (114-1, 114-2) that provides a number of advantages not previously offered including 1) both providing high current for facile crossbar array (FIG. 1, 100) access and non-linear selection, 2) providing quicker memory reads due to the quick relaxation time of the selectors (114); 3) providing asymmetrical selector designs; 4) reducing cost of manufacturing. However, it is contemplated that the devices and methods disclosed herein may prove useful in addressing other deficiencies in a number of technical areas. Therefore the systems and devices disclosed herein should not be construed as addressing just the particular elements or deficiencies discussed herein.

The preceding description has been presented to illustrate and describe examples of the principles described. This description is not intended to be exhaustive or to limit these principles to any precise form disclosed. Many modifications and variations are possible in light of the above teaching.

What is claimed is:

1. A memristive crossbar array, the crossbar array comprising:
a number of row lines;
a number of column lines intersecting the row lines to form a number of cross points; and
a number of memristor cells coupled between the row lines and the column lines at the cross points, a memristor cell comprising:
a memristive memory element to store information; and
multiple selectors electrically coupled to the memristive memory element, the multiple selectors to provide access to the memristive memory element.

2. The array of claim 1, wherein the multiple selectors are serially coupled to the memristive memory element.

3. The array of claim 1, wherein the multiple selectors are asymmetric selectors.

4. The array of claim 3, wherein:
a first selector is tuned towards a first voltage polarity; and
a second selector is tuned towards a second, and opposite, voltage polarity.

5. The array of claim 1, wherein a selector is a volatile selector comprising:
a first electrode;
a second electrode; and
an active region disposed between the first electrode and the second electrode;
in which the active region comprises cationic species that aggregate to form a conductive channel between the first electrode and the second electrode when a selecting voltage is applied and that dissipate when the selecting voltage is removed.

6. The array of claim 1, wherein the multiple selectors are non-liner selectors having a nonlinearity of greater than 1,000.

7. A system for accessing information in a memristive crossbar array, comprising:
a memristive crossbar array, the crossbar array comprising:
a number of memristor cells coupled between row lines and column lines of the memristive crossbar array, a memristor cell comprising:
a memristive memory element to store information; and
multiple selectors electrically coupled to the memristive memory element, the multiple selectors to provide access to the memristive memory element; and
a memory controller to provide access to the memristive memory element by providing an access voltage to a corresponding memristor cell.

8. The system of claim 7, wherein a memristor cell further comprises a number of interface layers disposed between the memristive memory element and the multiple volatile selectors.

9. The system of claim 7, wherein the multiple selectors return to a high resistance state when an access voltage is removed.

10. The system of claim 9, wherein the multiple selectors return to a high resistance state within 1 microsecond of removal of an access voltage.

11. The system of claim 7, wherein a voltage that generates a suppressed current level of the multiple selectors is greater than half of the access voltage.

12. The system of claim 7, wherein the memory controller allows access for a read operation and a write operation by providing an access voltage to both of the multiple selectors.

13. A method for making a memristive crossbar array, comprising:
providing a memristive memory element, the memristive memory element comprising:
a first memristor electrode;
a switching oxide disposed adjacent to the first electrode; and
a second memristor electrode disposed adjacent to the switching oxide;
providing multiple selectors, in which a volatile selector comprises:
a first selector electrode;
a second selector electrode; and
a selector active region disposed between the first selector electrode and the second selector electrode; and
electrically coupling the multiple selectors to the memristive memory element in series.

14. The method of claim 13, wherein the memristive memory element is disposed between the multiple selectors.

15. The method of claim 14, wherein a first selector is disposed between a second selector and the memristive memory element.
